(19) United States
(12) Patent Application Publication
(10) Pub. No.: US 2009/0114433 A1
(43) Pub. Date: May 7, 2009

(54) MULTI-LAYERED CERAMIC BOARD AND METHOD OF MANUFACTURING THE SAME

(75) Inventors: Min Ji KO, Suwon (KR); Eun Tae Park, Yongin (KR); Yong Seok Choi, Suwon (KR); Soo Hyun Lyoo, Yongin (KR)

Correspondence Address: MCDERMOTT WILL & EMERY LLP, 18191 VON KARMAN AVE., SUITE 500, IRVINE, CA, 92612-7108, US

(73) Assignee: SAMSUNG ELECTRO-MECHANICS CO., LTD., Suwon (KR)

(21) Appl. No.: 12/264,869

(22) Filed: Nov. 4, 2008

(30) Foreign Application Priority Data
Nov. 5, 2007 (KR) 10-2007-0112116

(51) Int. Cl. H05K 1/02; H05K 3/00

(52) U.S. Cl. 174/258; 29/829

(57) ABSTRACT

There is provided a multi-layered ceramic board and a method of manufacturing the same. A multi-layered ceramic board according to an aspect of the invention may include: an internal layer having a plurality of first dielectric sheets laminated, each of the first dielectric sheets prepared by mixing glass powder with a predetermined amount of alumina powder; and an external layer having at least one second dielectric sheet laminated on the surface of the internal layer, the second dielectric sheet prepared by mixing glass powder with alumina powder in a smaller amount than the first dielectric sheet, wherein via hole conductors and internal electrodes provided in the internal layer are electrically connected to a surface electrode provided on the surface of the external layer, and the internal layer, the external layer, the via hole conductors, the internal layer, and the surface electrode are fired at a predetermined temperature.

### CROSS-REFERENCE TO RELATED APPLICATIONS

This application claims the priority of Korean Patent Application No. 2007-0112116 filed on Nov. 5, 2007, in the Korean Intellectual Property Office, the disclosure of which is incorporated herein by reference.

### BACKGROUND OF THE INVENTION

1. Field of the Invention

The present invention relates to a multi-layered ceramic board and a method of manufacturing the same that can increase bonding strength between an electrode and ceramic and bending strength by varying degrees of crystallinity of the inside of the ceramic board and the surface of a ceramic board.

2. Description of the Related Art

With the technical development of various kinds of electronic products as well as the information communication technology, electronic components also need to be reduced in size and weight while achieving high performance. Therefore, it is necessary to improve the wiring density of a board, and at the same time, reduce the size of individual components or modules. To this end, research has been actively conducted to develop a technique that manufactures a ceramic board by laminating and firing dielectric sheets applied with electrode paste used to form an electrode.

A ceramic board needs to be formed of an electrode material with high electric resistance since it is fired at high temperature. However, a metal, such as silver (Ag) and copper (Cu), which has low electric resistance, needs to be used to manufacture a high frequency circuit board. Further, a mixture of crystalline or amorphous glass powder and ceramic powder is used, and fired together with the electrode material with low electric resistance.

Materials of low temperature co-fired ceramics (LTCC) require different characteristics that vary according to its purpose. A high speed signal wiring board requires a low dielectric constant and low dielectric loss. Components, such as filters using resonance, require a high dielectric constant. Components mounted onto mobile terminals require high strength.

FIG. 1 is a cross-sectional view illustrating a multi-layered ceramic board manufactured using a method according to the related art. Glass powder and alumina powder are mixed with each other, and the mixed powders are used to form a dielectric sheet 1.

Via hole conductors 2 and internal electrodes 3 are formed in the dielectric sheet 1, and a surface electrode 4 is formed on the surface thereof. Then, the dielectric sheet 1 including the via hole conductors 2 and the internal electrodes 3 and the surface electrode 4 are fired, thereby manufacturing a multi-layered ceramic board.

However, when a single ceramic material is used, the amount of the ceramic material crystallized at a predetermined temperature is constant in the entire amount. Therefore, if bending strength is increased, the bonding strength between an electrode and ceramic is reduced. When the degree of crystallinity is increased by increasing firing temperature so as to increase the bonding strength between the electrode and the ceramic, the bonding strength of the board is decreased.

### SUMMARY OF THE INVENTION

An aspect of the present invention provides a multi-layered ceramic board and a method of manufacturing the same that can increase bonding strength between an electrode and ceramic and bending strength varying according to degrees of crystallinity when dielectric sheets are fired by differing amounts of alumina powder between internal and external layers of a laminate including dielectric sheets formed of glass ceramics.

According to an aspect of the present invention, there is provided a multi-layered ceramic board including: an internal layer having a plurality of first dielectric sheets laminated, each of the first dielectric sheets prepared by mixing glass powder with a predetermined amount of alumina powder; and an external layer having at least one second dielectric sheet laminated on the surface of the internal layer, the second dielectric sheet prepared by mixing glass powder with alumina powder in a smaller amount than the first dielectric sheet, wherein via hole conductors and internal electrodes provided in the internal layer are electrically connected to a surface electrode provided on the surface of the external layer, and the internal layer, the external layer, the via hole conductors, the internal layer, and the surface electrode are fired at a predetermined temperature.

The internal layer may have the alumina powder in a larger amount than the external layer by 3 to 10 wt %.

The internal layer may have the alumina powder in a larger amount than the external layer by 5 to 7 wt %.

The internal layer may include 33 to 55 wt % of alumina powder.

The external layer may include 30 to 45 wt % of alumina powder.

The internal layer, the external layer, the via hole conductors, the internal layer, and the surface electrode may be co-fired.

According to an aspect of the present invention, there is provided a method of manufacturing a multi-layered ceramic board, the method including: forming an internal layer by laminating a plurality of first dielectric sheets prepared by mixing glass powder with alumina powder; forming an external layer by laminating a second dielectric sheet, prepared by mixing glass powder with alumina powder, on one surface of the internal layer or by laminating second dielectric sheets on upper and lower surfaces of the internal layer; forming a surface electrode on the surface of the external layer so that the surface electrode is electrically connected to via hole conductors and internal electrodes formed in the internal layer; and co-firing the internal layer, the external layer, the via hole conductors, the internal electrode, and the surface electrode.

The internal layer may have the alumina powder in a larger amount than the external layer by 3 to 10 wt %.

The internal layer may have the alumina powder in a larger amount than the external layer by 5 to 7 wt %.

The internal layer may include 33 to 55 wt % of alumina powder.

The external layer may include 30 to 45 wt % of alumina powder.

The external layer may be formed on the internal layer except for parts of the via hole conductors exposed to the outside environment through openings in the internal layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a multi-layered ceramic board according to the related art; and

FIG. 2 is a cross-sectional view illustrating a multi-layered ceramic board according to an exemplary embodiment of the invention.

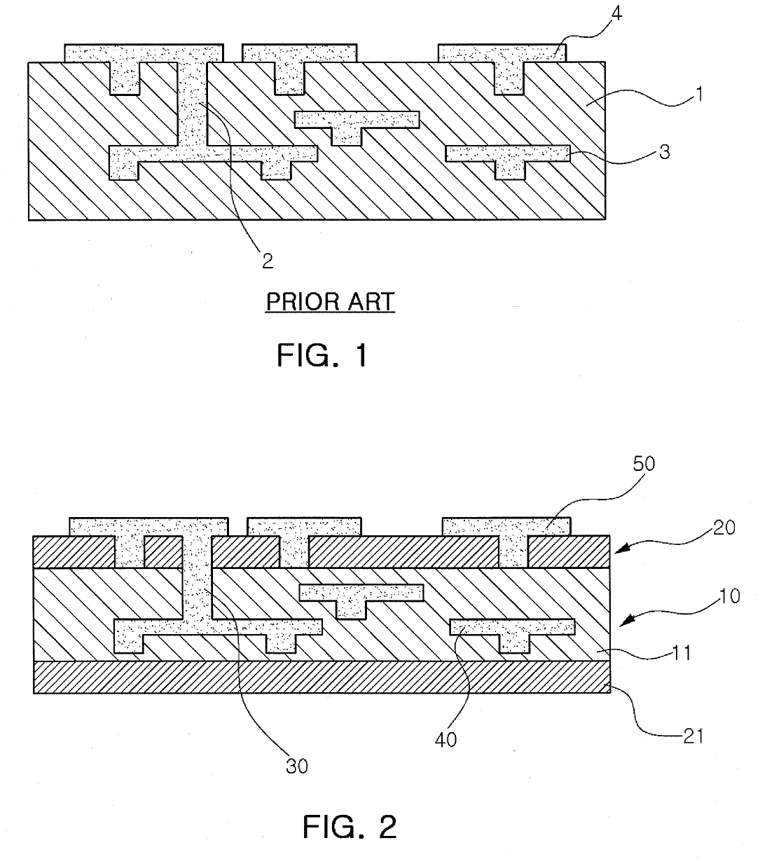

### DETAILED DESCRIPTION OF THE PREFERRED EMBODIMENT

Exemplary embodiments of the present invention will now be described in detail with reference to the accompanying drawings.

FIG. 2 is a cross-sectional view illustrating a multi-layered ceramic board according to an exemplary embodiment of the invention.

As shown in FIG. 2, a multi-layered ceramic board according to this embodiment includes an internal layer 10 and an external layer 20. A plurality of first dielectric sheets 11, formed by mixing glass powder with a predetermined amount of alumina powder with each other, are laminated to form the internal layer 10. At least one second dielectric sheet 21, formed by mixing glass powder and alumina powder in a smaller amount than the first dielectric sheet 11, is laminated on the surface of the internal layer 10, thereby forming the external layer 20. Via hole conductors 30 and internal electrodes 40 formed in the internal layer 10 are electrically connected to a surface electrode 50 formed on the surface of the external layer 20. Then, the internal layer 10, the external layer 20, the via hole conductors 30, the internal electrodes 40, and the surface electrode 50 are fired at a predetermined temperature to manufacture the multi-layered ceramic board.

Each of the first and second dielectric sheets 11 and 21 is formed by mixing a mixture of glass powder and an inorganic filler with an organic solvent and a binder, performing tape-casting using a doctor blade, and then cutting to a predetermined size.

The glass powder contains 10 to 55 wt % (percent by weight) of CaO, 45 to 70 wt % of SiO₂, 0 to 30 wt % of Al₂O₃, and up to 10 wt % of impurities.

Examples of the inorganic filler may include quartz, zirconia, and alumina. Alumina is used in this embodiment.

The first dielectric sheet 11 and the second dielectric sheet 21 have the same composition. However, the first dielectric sheet 11 contains alumina powder in a larger amount than the second dielectric sheet 21 by 3 to 10 wt %, preferably, 5 wt % to 7 wt %.

That is, since the total amount of alumina powder differs between the first and second dielectric sheets 11 and 21, when the first and second dielectric sheets 11 and 21 are fired at the same temperature, the first and second dielectric sheets 11 and 12 have different degrees of crystallinity.

Preferably, the first dielectric sheet 11 contains 33 to 55 wt % of alumina powder, and the second dielectric sheet 21 contains 30 to 45 wt % of alumina powder.

The via hole conductors 30 and the internal electrodes 40 are formed at predetermined positions of the first dielectric sheet 11. A necessary number of first dielectric sheets 11 are laminated to form the internal layer 10.

The external layer 20 is formed by laminating at least one second dielectric sheet 21 on the surface of the internal layer. Here, one second dielectric sheet may be laminated on one of an upper surface or a lower surface of the internal layer. Alternatively, second dielectric sheets may be laminated on upper and lower surfaces thereof. The second dielectric sheet is formed on the surface of the internal layer except for parts of the via hole conductors 30 included in the internal layer that are exposed to the outside through openings in the internal layer.

The surface electrode 50 is formed on the surface of the external layer 20, and is electrically connected to the via hole conductors 30. Therefore, the surface electrode 50 is electrically connected to the internal electrodes 40 through the via hole conductors 30.

The above-described multi-layered ceramic laminate is fired at a temperature of 830 to 900° C. to thereby manufacture a multi-layered ceramic board.

That is, the multi-layered ceramic board according to this embodiment laminates the first dielectric sheet 11 having a relatively large amount of alumina powder therein (internal layer), and laminates the second dielectric sheet 21 containing alumina powder in a relatively smaller amount than the first dielectric sheet 11 on the outside thereof of the internal layer (external layer) to prepare a multi-layered ceramic laminate. Then, the multi-layered ceramic laminate is fired to manufacture the multi-layered ceramic board.

Here, the first dielectric sheet 11 having a large amount of alumina powder has higher densification temperature and crystallization temperature than the second dielectric sheet 21 having a relatively smaller amount of alumina powder. Therefore, the internal layer is hardly crystallized and completely densified at a temperature in which the external layer is sufficiently crystallized.

In this case, since the internal layer that determines the bending strength of the material has a lower degree of crystallinity than the external layer, the internal layer has high bending strength. As the external layer is sufficiently crystallized, high bonding strength can be obtained between the surface electrode and the ceramic.

Hereinafter, a method of manufacturing a multi-layered ceramic board according to an exemplary embodiment of the invention will be described.

Glass powder that contains 10 to 55 wt % (percent by weight) of CaO, 45 to 70 wt % of SiO₂, 0 to 30 wt % of Al₂O₃, and up to 10 wt % of impurities is mixed with 33 to 55 wt % of alumina powder. The mixed powders are mixed with an organic solvent and a binder to produce slurry.

The slurry is tape cast using a doctor blade method, and cut to a predetermined size to form the first dielectric sheet 11.

Via hole conductors and internal electrodes are formed at predetermined positions of the first dielectric sheet 11. A necessary number of first dielectric sheets 11 are laminated to form the internal layer.

The second dielectric sheet 21 is formed by the same method as that used to form the first dielectric sheet 11 except that the second dielectric sheet 21 has 30 to 45 wt % of alumina powder. Here, the second dielectric sheet 21 has alumina powder in a smaller amount than the first dielectric sheet 11 by 3 to 10 wt %, preferably, 5 to 7 wt %.

The formed second dielectric sheet 21 is laminated on one surface of the internal layer. Alternatively, the second dielectric sheets 21 may be formed on upper and lower surfaces of the internal layer. Here, the external layer is formed on the surface of the internal layer except for parts of the via hole conductors that are exposed to the outside environment through openings in the internal layer.

Then, the surface electrode is formed on the surface of the external layer so that the surface electrode is electrically connected to the internal electrodes formed in the internal layer.

Then, the internal layer, the external layer, the via hole conductors, the internal electrodes, and the surface electrode are co-fired to thereby manufacture a multi-layered ceramic board.

In Table 1, physical characteristics of a ceramic board manufactured according to the above-described manufacturing method are compared with those of a ceramic board manufactured according to the related art. Here, the physical characteristics vary according to a change in the amounts of alumina powder of the internal and external layers.

TABLE 1

| | Alumina content | | | | | |
|---|---|---|---|---|---|---|
| | Internal | External | Firing | bending | bonding | |
| | layer | layer | temperature | strength | strength | |
| Related art | 40 wt % | | | 280 MPa | 5 | kgf |
| First | 35 wt % | 30 wt % | — | — | — | |
| embodiment | | | | | | |
| Second | 40 wt % | 35 wt % | 850° C. | 300 MPa | 5 | kgf |
| embodiment | | | | | | |
| Third | 45 wt % | 40 wt % | 870° C. | 320 MPa | 63 | kgf |
| embodiment | | | | | | |
| Fourth | 50 wt % | 45 wt % | 890° C. | 330 MPa | 81 | kgf |
| embodiment | | | | | | |

In the related art, when the internal layer and the external layer have the same content (40 wt %), the ceramic board has a bending strength of 280 MPa, and a bonding strength of 1.5 kgf.

In a case of the first embodiment, since the external layer has alumina powder in a smaller amount that the internal layer, the external layer is not crystallized even at high temperatures.

Like the second and third embodiments, when a difference in amount between the internal layer and the external layer is approximately 5 wt %, the bending strength and the bonding strength are shown to increase.

As set forth above, according to exemplary embodiments of the invention, bonding strength between an electrode and ceramic and bending strength that vary according to degrees of crystallinity when dielectric sheets are fired can be increased at the same time by differing amounts of alumina powder between internal and external layers of a laminate.

While the present invention has been shown and described in connection with the exemplary embodiments, it will be apparent to those skilled in the art that modifications and variations can be made without departing from the spirit and scope of the invention as defined by the appended claims.

What is claimed is:

1. A multi-layered ceramic board comprising:
an internal layer having a plurality of first dielectric sheets laminated, each of the first dielectric sheets prepared by mixing glass powder with a predetermined amount of alumina powder; and
an external layer having at least one second dielectric sheet laminated on the surface of the internal layer, the second dielectric sheet prepared by mixing glass powder with alumina powder in a smaller amount than the first dielectric sheet,
wherein via hole conductors and internal electrodes provided in the internal layer are electrically connected to a surface electrode provided on the surface of the external layer, and the internal layer, the external layer, the via hole conductors, the internal layer, and the surface electrode are fired at a predetermined temperature.

2. The multi-layered ceramic board of claim 1, wherein the internal layer has the alumina powder in a larger amount than the external layer by 3 to 10 wt %.

3. The multi-layered ceramic board of claim 2, wherein the internal layer has the alumina powder in a larger amount than the external layer by 5 to 7 wt %.

4. The multi-layered ceramic board of claim 1, wherein the internal layer comprises 33 to 55 wt % of alumina powder.

5. The multi-layered ceramic board of claim 1, wherein the external layer comprises 30 to 45 wt % of alumina powder.

6. The multi-layered ceramic board of claim 1, wherein the internal layer, the external layer, the via hole conductors, the internal layer, and the surface electrode are co-fired.

7. A method of manufacturing a multi-layered ceramic board, the method comprising:
forming an internal layer by laminating a plurality of first dielectric sheets prepared by mixing glass powder with alumina powder;
forming an external layer by laminating a second dielectric sheet, prepared by mixing glass powder with alumina powder, on one surface of the internal layer or by laminating second dielectric sheets on upper and lower surfaces of the internal layer;
forming a surface electrode on the surface of the external layer so that the surface electrode is electrically connected to via hole conductors and internal electrodes formed in the internal layer; and
co-firing the internal layer, the external layer, the via hole conductors, the internal electrode, and the surface electrode.

8. The method of claim 7, wherein the internal layer has the alumina powder in a larger amount than the external layer by 3 to 10 wt %.

9. The method of claim 8, wherein the internal layer has the alumina powder in a larger amount than the external layer by 5 to 7 wt %.

10. The method of claim 7, wherein the internal layer comprises 33 to 55 wt % of alumina powder.

11. The method of claim 7, wherein the external layer comprises 30 to 45 wt % of alumina powder.

12. The method of claim 7, wherein the external layer is formed on the internal layer except for parts of the via hole conductors exposed to the outside environment through openings in the internal layer.
